(19) United States
(12) Patent Application Publication
(10) Pub. No.: US 2015/0036307 A1
(43) Pub. Date: Feb. 5, 2015

(54) CIRCUIT BOARD

(71) Applicant: Novalia Ltd, Cambridge (GB)

(72) Inventor: Kate Stone, Cambridge (GB)

(73) Assignee: Novalia Ltd., Cambridge (GB)

(21) Appl. No.: 14/382,524

(22) PCT Filed: Feb. 28, 2013
(86) PCT No.: PCT/GB2013/050503

§ 371 Date: Sep. 2, 2014

(30) Foreign Application Priority Data
Mar. 2, 2012 (GB) 1203728.9

(51) Int. Cl. H05K 1/09; H05K 1/02; H05K 3/30; H05K 1/18; H05K 3/12; H05K 3/10; H05K 1/11; H05K 1/03

(52) U.S. Cl. CPC H05K 1/092; H05K 1/111; H05K 1/028; H05K 1/0386; H05K 1/181; H05K 3/125; H05K 3/103; H05K 3/301; H05K 3/305
USPC 361/767; 174/261; 174/257; 174/258; 427/98.4; 156/291

(57) ABSTRACT

A circuit board is described. The circuit board comprises a substrate (4), a set of contact pads (6) supported on the substrate and a plurality of discrete adhesive conductive regions disposed on the contact pads and the substrate such that at some adhesive conductive regions are disposed on and between two contact pads.

### FIELD OF THE INVENTION

The present invention relates to a circuit board.

### BACKGROUND

Electronic components are increasingly being incorporated into printed articles, such as books, posters and greeting cards, to allow printed articles to become more interactive. Examples of interactive printed articles are described in GB 2 464 537 A, WO 2004 077286 A, WO 2007 035115 A and DE 1993 4312672 A.

Conventionally, discrete devices (such as capacitors) and packaged devices (such as microcontrollers) are mounted to a printed wiring board and the printed wiring board is mounted to or inserted into the printed article.

### SUMMARY

The present invention seeks to facilitate incorporation of devices into articles, such as games, books, greeting cards, product packaging and posters.

According to a first aspect of the present invention there is provided a circuit board which comprises a substrate, a set of contact pads supported on the substrate and a plurality of discrete adhesive conductive regions disposed on the contact pads and the substrate such that at some adhesive conductive regions are disposed on and between two contact pads.

This allows the conductive adhesive to be applied over a wide area of the substrate without the need for aligning the conductive adhesive to the contact pads.

The substrate may comprise a flexible substrate. The substrate may comprise paper, card or cardboard. The paper or card may comprise formable paper or card. The substrate may be shaped (or “moulded”). For example, the substrate may be embossed. The substrate may comprise plastic, such as polyethylene terephthalate (PET), polypropylene (PP) or polyethylene naphthalate (PEN). The substrate may comprise a laminate, for example comprising a layer of fibre-based material covered by a layer of plastic or sandwiched between two layers of plastic. By using a fibre-based material, less material can be used which can be environmentally friendly. The fibre-based material may comprise recycled material. The substrate may be rigid.

The contact pads may comprise conductive ink, such as silver-, copper- or carbon-based conductive ink, and/or conductive foil. The conductive ink may be printed, for example, by flexographic printing. The conductive ink may include a non-conductive adhesive. The conductive ink may be water based. The conductive ink may be solvent based. The conductive ink may be curable, for example using ultraviolet (UV) light.

The adhesive conductive regions may comprise conductive ink, conductive glue and or conductive tape. The conductive ink may be silver-, copper- or carbon-based conductive ink. The adhesive conductive regions may comprise a pressure-sensitive adhesive.

The conductive ink may include a non-conductive adhesive. The conductive ink or glue may be water based. The conductive ink or glue may be solvent based. The conductive ink may be curable, for example using ultraviolet (UV) light. The conductive ink or glue can take the form of paste, i.e. a conductive paste.

The adhesive conductive regions may be arranged in an array. For example, the array may comprise a rectangular or hexagonal array. The adhesive conductive regions may be arranged in a random pattern. The adhesive conductive regions may include different patterns and/or different arrays, for example, on different parts of the substrate.

The two contact pads are separated by a minimum spacing, s, in a given direction and the adhesive conductive regions may have a maximum extent, w, in the given direction less than the minimum spacing. This can help to avoid forming a short between the contact pads.

The maximum extent, w, may be substantially the same before and after mounting a module over the two contact pads. For example, the adhesive conductive regions may be a foil or a suitably viscous liquid.

The maximum extent, w, may be no more than 2 mm or no more than 1 mm. the maximum extent, w, may be no more than 500 μm, no more than 200 μm or no more than 100 μm.

The two contact pads may comprise sections or ends of conductive tracks.

The substrate may be provided by a printed article or part of printed article, wherein the indicia are provided on the substrate.

A water-based conductive ink or glue may have an application viscosity between 90 to 300 centipoise (cP). A UV-cured conductive ink or glue may have an application viscosity of about 250 to 600 cP. A solvent-based conductive ink or glue may have an application viscosity of 100 to 500 cP.

A water- or solvent-based conductive ink may have a solid content of 15 to 80% solids by volume and/or up to 95% by weight. A UV-cured conductive ink may be considered effectively to be 100% by volume or weight.

Conductive ink or glue, for example the first and/or second contact pads and/or bonding material, may have a (dry) thickness of at least 1 μm or at least 2 μm. The conductive ink or glue may have a thickness of at least 5 μm or at least 10 μm. The conductive ink or glue may have a thickness no more than 100 μm or no more than 50 μm. The conductive ink or glue may have a thickness of no more than 20 μm or no more than 10 μm.

The discrete adhesive conductive regions may adhere with a counterpart adhesive conductive region, i.e. be part of a two-part adhesive system.

The discrete adhesive conductive regions may be applied to the circuit board and/or to a module or device. For example, one set of discrete adhesive conductive regions may be applied over contact pads and a substrate of a module or device. The contact pads may be bond pads and the substrate may be a module circuit board or a semiconductor die.

According to a second aspect of the present invention there is provided a circuit board assembly comprising the circuit board and a module or device mounted on the circuit board by the discrete adhesive conductive regions.

According to a third aspect of the present invention there is provided a device or module comprising a substrate, a set of contact pads supported on the substrate and a plurality of discrete adhesive conductive regions disposed on the contact pads and the substrate such that at least some adhesive conductive regions are disposed on and between two contact pads.

According to a fourth aspect of the present invention there is provided a circuit board assembly comprising the circuit board and a module or device mounted on the circuit board by the discrete adhesive conductive regions.

The module may comprise a module substrate and a device mounted on the module substrate. The device may comprise a semiconductor die. The device may comprise a microcontroller.

The circuit board substrate may support one or more capacitive touch switches, for example in the form a finger-tip-sized (e.g. having an area of between 0.2 mm2 to 2 mm2) and/or an array of touch electrodes for a touch panel. Thus, a microcontroller and other devices may be directly mounted or mounted via one or more other substrates to form an enhanced printed matter (such as poster or greeting card) which a user can provide input using touch.

According to a fifth aspect of the present invention there is provided a method comprising providing a substrate, providing a set of contact pads on the substrate and forming a plurality of discrete adhesive conductive regions over the contact pads and substrate such that at some adhesive conductive regions are disposed on and between two contact pads.

The method may further comprise mounting a module over the contact pads by the discrete adhesive conductive regions. Forming the discrete adhesive conductive regions may comprise printing conductive ink or glue onto the contact pads and substrate. Forming the discrete adhesive conductive regions may comprise applying adhesive conductive tape onto the contact pads and substrate.

### BRIEF DESCRIPTION OF THE DRAWINGS

FIG. 1 is a simplified, perspective view of part of a circuit board assembly;

FIG. 2 is a simplified, perspective view of a module; and

FIG. 3 illustrates mounting a module to a circuit board;

FIG. 4 is a plan view of first and second contact pads;

FIG. 5 illustrates a first pattern of adhesive conductive regions;

FIG. 6 illustrates spreading of adhesive conductive regions;

FIG. 7 illustrates a second pattern of adhesive conductive regions;

FIG. 8 illustrates a third pattern of adhesive conductive regions; and

FIG. 9 illustrates a circuit board.

### Detailed Description of Certain Embodiments

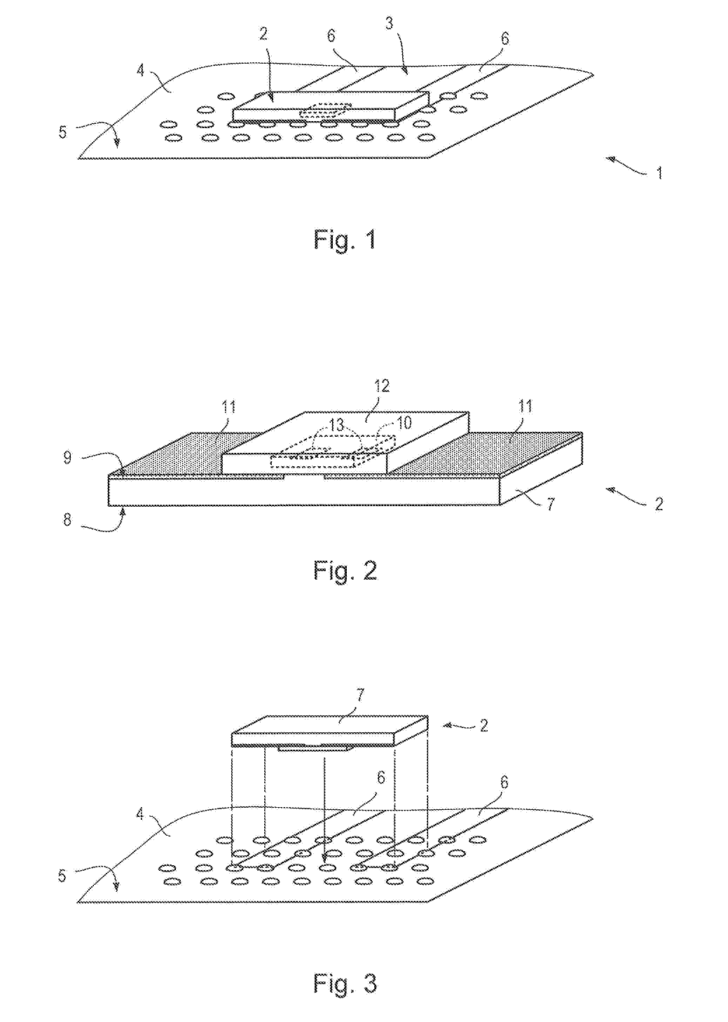

FIG. 1 shows part of flexible circuit board assembly 1.

The circuit board assembly 1 comprises a module 2 and a circuit board 3. The circuit board 3 includes a flexible substrate 4 having a face 5 which supports a set of contact pads 6 (herein also referred to as “conductive regions”). The substrate 4 is formed from an insulating material, such as card, paper or plastic. The substrate 4 may take the form of a sheet of card or paper. The substrate 4 may be a laminate. In this example, only two contact pads 6 are shown. However, many contact pads 6, for example twenty or more, can be provided.

The contact pads 6 comprise conductive ink, such as silver-based conductive ink, and may be formed directly on the circuit board substrate 4. The contact pads 6 may be discrete pads which are connected to a set of conductive tracks (not shown). However, the contact pads 6 may be provided by sections or ends of conductive tracks. In some examples, the contact pads 6 may be provided by metallic foil, for example formed directly on the circuit board substrate 4. The contact pads 6 may have dimensions (e.g. width and/or length) of at least 100 μm. For example, the contact pads 6 have width of between 1 and 10 mm.

Referring also to FIG. 2, the module 2 comprises a flexible substrate 7, for example a sheet of card or plastic, having first and second faces 8, 9, a device 10 and a set of contact pads 11 (herein also referred to as “conductive regions”) supported on a first face 8 of the substrate 7. The module 2 may include a protective cover 12 which covers the device. The contact pads 11 comprise conductive ink, such as silver-based conductive ink, and may be formed directly on the module substrate 7. In some examples, the contact pads 11 may be provided by metallic foil. The contact pads 11 may have dimensions (e.g. width and/or length) of at least 100 μm. For example, the contact pads 11 have width of between 1 and 10 mm.

The device 10 includes a set of terminals 13, such as bond pads. Typically, terminals 13 have dimensions of about 100 μm. However, the terminals 13 can be bigger. In this example, a simple two-terminal device 10 is shown. However, the device 10 may have many terminals, for example twenty terminals or more. The terminals 13 are electrically connected to the contact pads 11. For example, each terminal 13 fully or partially overlaps a respective contact pad 11 and is attached using conductive glue, ink or tape (not shown).

Suitable modules and a method of making such modules are described in GB 2 472 047 A which is incorporated herein by reference.

The circuit board 3 is covered by a set of discrete adhesive conductive regions 15 (herein also referred to as “conductive bond dots”). Additionally or alternatively, the module 3 may be covered by a set of discrete adhesive conductive regions (not shown). In this example, the conductive regions 15 are arranged in an array and comprise conductive ink. The conductive ink may be pressure sensitive. The module 2 is mounted on the circuit board 3 using at least some of the adhesive conductive regions 15.

Referring to FIG. 3, regions of liquid conductive ink 15′ are applied across the circuit board 3. Conductive ink regions 15′ are applied on and around (including between) the contact pads 6. At least one region 15′ is disposed on each contact pad 6 and at least one region 15′ is disposed between each contact pad 6.

One or more slots (not shown) may be provided in the circuit board substrate 4 as described in GB 2 453 765 A to control unwanted flow of ink 15′ and prevent short circuits.

The conductive ink regions 15′ may be applied, for example by inkjet printing, lithographic printing, screen printing or gravure printing, onto the circuit board 3 including the substrate 4 and contact pads 6 before bringing the module 2 and circuit board 3 together. The module 2 and circuit board 3 are aligned and brought into contact. The wet regions of conductive ink 15′ is cured, for example by allowing it dry or by using IR or UV radiation, to form dry regions of conductive ink 15.

The adhesive conductive regions 15 provide electrical interconnection between the circuit board contact pads 6 and the module contact pads 11. Moreover, the adhesive conductive regions 15 mechanically bond the module 2 and circuit board 3. In particular, adhesive conductive region(s) 15 disposed between the circuit board contact pads 6 may not provide any electrical interconnection, but still serve to secure the module 2 to the circuit board 3.

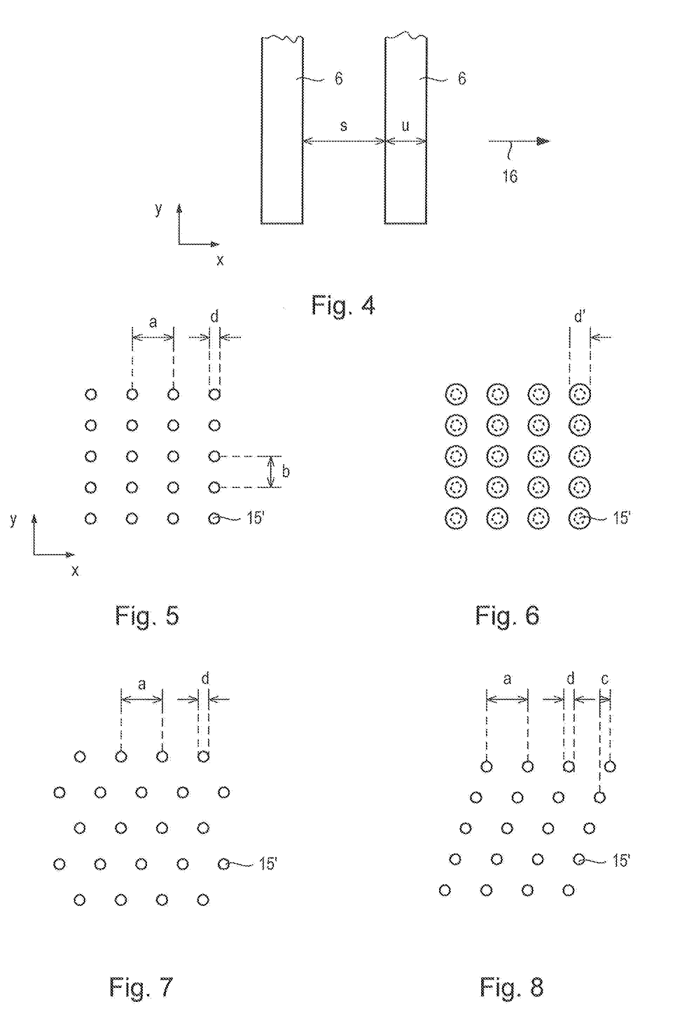

Referring to FIG. 4, adjacent contact pads 6 are separated by a distance, s, along a direction 16 (in this case, along the x-axis) herein referred to as a spacing direction. In this direction 16, the contact pads 6 have a width, u. In FIG. 4, the contact pads 6 extend in parallel in a perpendicular direction (along the y-axis). However, the contact pads 6 can extend along the x-axis or in another direction.

Referring to also to FIG. 5, the adhesive conductive regions 15′ have a width, d, along the spacing direction 16. In this example, the adhesive conductive regions 15′ are circular in plan view and so the width is the diameter of the region 15′.

Adjacent regions 15′ are spaced apart along the spacing direction with a pitch, a. The width, d, and pitch, a, are chosen such that the adhesive conductive regions 15′ do not overlap and, thus, form a short.

Referring also to FIG. 6, the width and pitch may be chosen to take into account spread of ink so that it has a larger width, d′ (d′>d), for example due to compression of a drop of ink between surfaces, due to capillary action and/or due to surface wetting (or “spreading”).

Values for width, d (or d′), and pitch, a, may be found using:

min(s,u)≧a>d>0 (1)

According to equation (1) above, a portion of at least one region 15′ is disposed on each contact 6 and a portion of at least one region 15′ is disposed between adjacent contacts 15′. Some examples of values include: for s=2 mm and u=1 mm, (i) d=0.5 mm and a=1 mm (i.e. u=a=2 d), (ii) d=0.5 mm and a=0.75 mm (i.e. 0.75 u=a=1.5 d), (iii) d=0.25 mm and a=1 mm (i.e. u=a=2 d) and (iv) d=0.25 mm and a=0.75 mm (i.e. 0.75 u=a=2 d). In examples (i) and (iii), two regions 15′ might partially overlap a contact pad 6. The degree of overlap can be increased by reducing the pitch, a, of two regions 15′. In example (ii), two regions 15′ might still partially overlap a contact pad 6, but the degree of overlap is increased.

Additionally or alternatively, values for width, d (or d′), and pitch, a, may be found using:

min(s,u)≧a+d>0 (2)

According to equation (2), at least one region 15′ is disposed on each contact 6 and at least one region 15′ is disposed between adjacent contacts 15′. In example (iv), at least one region 15′ fully overlaps a contact pad 6.

Similar values (including another pitch, b) can be found for contact pads 6 which are spaced along the y-axis. Depending on the size and arrangement of contact pads 6 and the geometry of the conductive regions 15, the values of a and b may differ. However, the same pitch, i.e. the same values a and b can be used, by finding first values a′ and b′, picking the smallest value (i.e. min(a′, b′)) and using the smallest value (i.e. a=b=min(a′, b′)).

In the example shown in FIG. 5, a rectangular array is shown.

Referring to FIG. 7, other regular arrays such as a hexagonal array may be used. However, similar considerations are taken into account and values for a and d can be found in the same or similar way.

Referring to FIG. 8, a row or line of conductive regions 15′ can be offset from an adjacent line by a value, c, were c<a and, optionally, c<d.

The module 2 and the circuit board assembly 1 can be assembled in substantially the same way, for example, using a continuous sheet process or other high-volume process which can be carried out using printing and/or converting processes (such that as described in GB 2 472 047 A). Pick-and-place robots can be used.

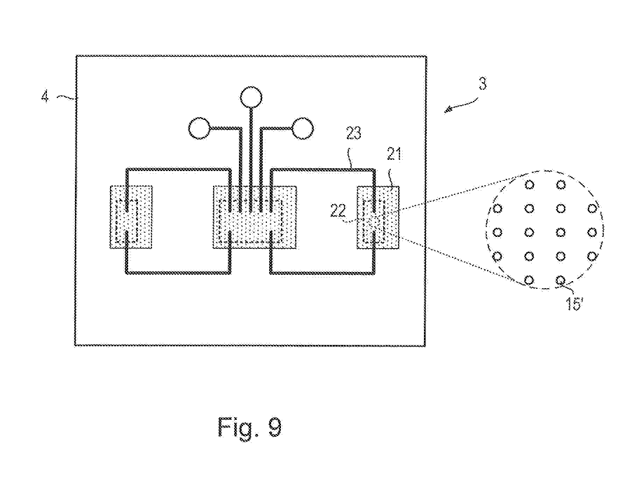

Referring to FIG. 9, areas (or “fields”) 21 of discrete adhesive conductive regions 15′ can be printed on the circuit board 3 in and around areas 22 where modules 2 or devices 10 are to be attached.

As shown in FIG. 9, the areas 21 of discrete adhesive conductive regions 15′ need not be accurately positioned with respect to conductive tracks 23 (the ends of which serve as contact pads 6) or the intended locations of modules 2 and devices 10.

This can help to simplify and reduce the cost of manufacture and/or increase throughput.

However, in some embodiments, the one side of the circuit board 3 can be covered by discrete adhesive conductive regions 15′. This can help to simplify and reduce the cost of manufacture even more.

In the examples hereinbefore described, the discrete adhesive conductive regions are provided by conductive ink or glue which can be applied by printing.

The discrete adhesive conductive regions 15 can take the form of pads of conductive tape. The tape can be transferred from a roll. For example, the roll may take the form of preformed pads supported on a backing sheet. Alternatively, the roll may take the form of a sheet of tape, and the pads of tape can be transferred by stamping.

It will be appreciated that many modifications may be made to the embodiments hereinbefore described.

Devices (such as a semiconductor die) can be mounted directly to the circuit board without using a module.

The adhesive conductive regions need not be circular. For example, adhesive conductive regions can be oval. Adhesive conductive regions can be polygonal, for example, a triangle or a (convex or concave) quadrilateral, such as a rectangle, rhombus or square.

Conductive ink need not be used for contact pads and/or tracks. For example, de-metallised film may be used wherein a layer of metal (such as aluminium) which coats a plastic film (such as PET) is partially removed (i.e. de-metallised) by masking and then etching to leave electrodes and tracks.

Adhesives which comprise of two parts which are applied to different surfaces may be used. Thus, a discrete adhesive conductive region may adhere (and, optionally, may only adhere) with a counterpart adhesive conductive region which may be supported on another surface.

The substrate need not be flat. The substrate may be shaped (or “moulded”), for example, to be embossed and/or to be contoured. Thus, the device can take the form of three-dimensional (i.e. non-flat) article, such as a computer mouse. A substrate may be formed from formable paper or card, such as Billerud FibreForm (RTM).

The first and/or second substrates may have different outline shapes. For example, the substrates need not have straight edges, but can have curved edges. The first and/or second substrates may include slots, slits, holes (which are relatively small compared to the size of a substrate) and/or apertures (which are relatively large compared to the size of a substrate).

1. A circuit board comprising:
a substrate;
a set of contact pads supported on the substrate; and
a plurality of discrete adhesive conductive regions disposed on the contact pads and the substrate such that at least some adhesive conductive regions are disposed on and between two contact pads.

2. A circuit board according to claim 1, wherein the substrate comprises a flexible substrate or a rigid substrate.

3. A circuit board according to claim 1, wherein the substrate comprises paper, card or cardboard.

4. A circuit board according to claim 1, wherein the substrate comprises plastic.

5. A circuit board according to claim 1, wherein the contact pads comprise conductive ink.

6. A circuit board according to claim 1, wherein the contact pads comprise conductive foil.

7. A circuit board according to claim 1, wherein the discrete adhesive conductive regions comprises conductive ink.

8. A circuit board according to claim 1, wherein the discrete adhesive conductive regions comprises conductive glue.

9. A circuit board according to claim 1, wherein the discrete adhesive conductive regions comprises conductive tape.

10. A circuit board according to claim 1, wherein the discrete adhesive conductive regions are arranged in an array.

11. A circuit board according to claim 10, wherein the array comprises a rectangular or hexagonal array.

12. A circuit board according to claim 1, wherein the discrete adhesive conductive regions are arranged in a random pattern.

13. A circuit board according to claim 1, wherein the two contact pads are separated by a minimum spacing, s, and the adhesive conductive regions have a maximum extent, w, between the two contact pads less than the minimum spacing.

14. A circuit board according to claim 13, wherein the maximum extent, w, is substantially the same before and after mounting a module over the two contact pads.

15. A circuit board according to claim 14 or 15, wherein the maximum extent, w, is no more than 2 mm or no more than 1 mm.

16. A circuit board according to claim 14, wherein the maximum extent, w, is no more than 500 μm, no more than 200 μm or no more than 100 μm.

17. A circuit board according to claim 1, wherein the two contact pads comprise sections or ends of conductive tracks.

18. An article according to claim 1, wherein the substrate is provided by a printed article or part of printed article, wherein the indicia are provided on the substrate.

19. A circuit board assembly comprising:
a circuit board according to claim 1; and
a device or module mounted on the circuit board by the discrete adhesive conductive regions.

20. A device or module comprising:
a substrate;
a set of contact pads supported on the substrate; and
a plurality of discrete adhesive conductive regions disposed on the contact pads and the substrate such that at least some adhesive conductive regions are disposed on and between two contact pads.

21. A circuit board assembly comprising:
a circuit board; and
a device or module according to claim 20 mounted on the circuit board by the discrete adhesive conductive regions.

22. A circuit board assembly comprising:
a circuit board according to claim 19; and
a device or module having,
a substrate;
a set of contact pads supported on the substrate; and
a plurality of discrete adhesive conductive regions disposed on the contact pads and the substrate such that at least some adhesive conductive regions are disposed on and between two contact pad,
wherein the device or module is mounted on the circuit board by the discrete adhesive conductive regions.

23. A circuit board assembly according to claim 19, wherein the module comprises:
a module substrate; and
a device mounted on the module substrate.

24. A method comprising:
providing a substrate;
providing a set of contact pads on the substrate; and
forming a plurality of discrete adhesive conductive regions over the contact pads and substrate such that at some adhesive conductive regions are disposed on and between two contact pads.

25. A method according to claim 24, further comprising:
mounting a module over the contact pads by the discrete adhesive conductive regions.

26. A method according to claim 25, wherein forming the discrete adhesive conductive regions comprises:
printing conductive ink or glue onto the contact pads and substrate.

27. A method according to claim 25, wherein forming the discrete adhesive conductive regions comprises:
applying adhesive conductive tape onto the contact pads and substrate.
